(19) United States
(12) Patent Application Publication
(10) Pub. No.: US 2026/0150609 A1
(43) Pub. Date: May 28, 2026

(54) SEMICONDUCTOR PROCESSING GRINDSTONE, SEMICONDUCTOR PROCESSING TOOL, PROCESSING METHOD, AND MANUFACTURING METHOD OF SEMICONDUCTOR PARTS

(71) Applicant: DISCO CORPORATION, Tokyo (JP)

(72) Inventor: Mitsuhiro Nomura, Tokyo (JP)

(21) Appl. No.: 19/368,747

(22) Filed: Oct. 24, 2025

(30) Foreign Application Priority Data
Nov. 22, 2024 (JP) 2024-203838

(51) Int. Cl. H10P 52/00; B24B 7/22

(52) U.S. Cl. CPC H10P 52/00; B24B 7/228

(57) ABSTRACT

Provided is a semiconductor processing grindstone used for processing a workpiece including a semiconductor as a material. The semiconductor processing grindstone includes abrasive grains and a binder that binds the abrasive grains together. The binder includes magnesium oxide and magnesium salt.

### BACKGROUND OF THE INVENTION

### Field of the Invention

The present invention relates to a semiconductor processing grindstone used for processing a workpiece that includes a semiconductor as a material, such as a semiconductor wafer, and a semiconductor processing tool. Moreover, the present invention relates to a processing method using the semiconductor processing grindstone and a manufacturing method of semiconductor parts.

### Description of the Related Art

Device chips mounted on electronic appliances including mobile phones and personal computers are manufactured through processing of semiconductor wafers.

On one side of a plate-shaped semiconductor wafer, a plurality of planned dividing lines (streets) are set in a grid pattern, and such devices as integrated circuits (ICs) and large scale integration (LSI) circuits are formed in rectangular regions partitioned by the planned dividing lines. The semiconductor wafer on which the devices are formed is divided into a plurality of device chips by being cut along each of the planned dividing lines.

In recent years, in manufacturing such device chips, wafers are thinned to make the chips smaller and lighter. For example, in a manufacturing process of the device chips described above, a wafer which has devices formed on a face side thereof is thinned in whole by being ground on a reverse side thereof by grindstones.

Grindstones used for grinding the wafer include abrasive grains and a binder and are formed by the abrasive grains being bound by the binder. Various types of binders are available for grindstones, and, for example, Japanese Patent Laid-open No. 2023-83679 discloses a grindstone of a type called a vitrified bonded grindstone which is formed by a binder mainly including a vitreous material such as silicon dioxide (SiO₂).

In addition, a resin bonded grindstone including resin in the binder and a metal bonded grindstone including metal in the binder, for example, are used for processing semiconductor parts, in some cases.

Each of these types of grindstones has advantages and disadvantages. For example, resin bonded grindstones are excellent in self-sharpening and maintaining processing quality but are inferior in durability. Metal bonded grindstones are excellent in durability but are inferior in self-sharpening and likely to cause dulling and loading. Vitrified bonded grindstones are also hard and less likely to be worn but have difficulty in self-sharpening. Moreover, vitrified bonded grindstones also have problems of deterioration of abrasive grains and energy consumption associated with heating due to being sintered at high temperature upon manufacture.

### SUMMARY OF THE INVENTION

Accordingly, an object of the present invention is to provide a new type of semiconductor processing grindstone that can be used for processing an object including a semiconductor as a material, a semiconductor processing tool using the semiconductor processing grindstone, a processing method using the semiconductor processing grindstone, and a manufacturing method of semiconductor parts.

In accordance with an aspect of the present invention, there is provided a semiconductor processing grindstone used for processing a workpiece including a semiconductor as a material, the semiconductor processing grindstone including abrasive grains and a binder that binds the abrasive grains together, in which the binder includes magnesium oxide and magnesium salt.

According to the aspect of the present invention, the semiconductor processing grindstone is used for at least one of cutting processing that cuts the workpiece, grinding processing that grinds the workpiece, or polishing processing that polishes the workpiece.

In accordance with another aspect of the present invention, there is provided a semiconductor processing tool used for processing a workpiece including a semiconductor as a material, the semiconductor processing tool including a semiconductor processing grindstone including abrasive grains and a binder that binds the abrasive grains together, the binder including magnesium oxide and magnesium salt.

In accordance with a further aspect of the present invention, there is provided a processing method that uses a semiconductor processing grindstone and processes a workpiece including a semiconductor as a material, the processing method including preparing the semiconductor processing grindstone including abrasive grains and a binder that binds the abrasive grains together, the binder including magnesium oxide and magnesium salt, supporting the workpiece, and processing the supported workpiece by using the semiconductor processing grindstone.

According to the further aspect of the present invention, preferably, at least one of cutting processing that cuts the workpiece, grinding processing that grinds the workpiece, or polishing processing that polishes the workpiece is carried out.

According to the further aspect of the present invention, preferably, in processing the workpiece, water is supplied to at least one of the workpiece or the semiconductor processing grindstone.

According to the further aspect of the present invention, preferably, in processing the workpiece, liquid property of the supplied water is changed such that the water has a pH value of equal to or more than 8 but equal to or less than 14 by causing the water to come into contact with the binder.

In accordance with a still further aspect of the present invention, there is provided a manufacturing method of semiconductor parts for manufacturing semiconductor parts by using a semiconductor processing grindstone and processing a workpiece including a semiconductor as a material, the manufacturing method including preparing the semiconductor processing grindstone including abrasive grains and a binder that binds the abrasive grains together, the binder including magnesium oxide and magnesium salt, supporting the workpiece, and processing the supported workpiece by using the semiconductor processing grindstone.

The semiconductor processing grindstone according to the present invention provides the semiconductor processing grindstone including magnesia cement as a binder, as a new type of grindstone that can be used for semiconductor processing. Moreover, a semiconductor processing tool using the semiconductor processing grindstone, a processing method using the semiconductor processing grindstone, and a manufacturing method of semiconductor parts are provided.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating a form of a grinding wheel;

FIG. 2 is a side elevational view schematically illustrating a manner of grinding processing performed on a workpiece by a grinding apparatus;

FIG. 3 is a flowchart describing an example of steps related to a processing method of a workpiece and a manufacturing method of semiconductor parts;

FIG. 4 is an exploded perspective view schematically illustrating a form of a cutting unit; and

FIG. 5 is a side elevational view schematically illustrating a manner of cutting processing performed on the workpiece by a cutting apparatus.

### DETAILED DESCRIPTION OF THE PREFERRED EMBODIMENT

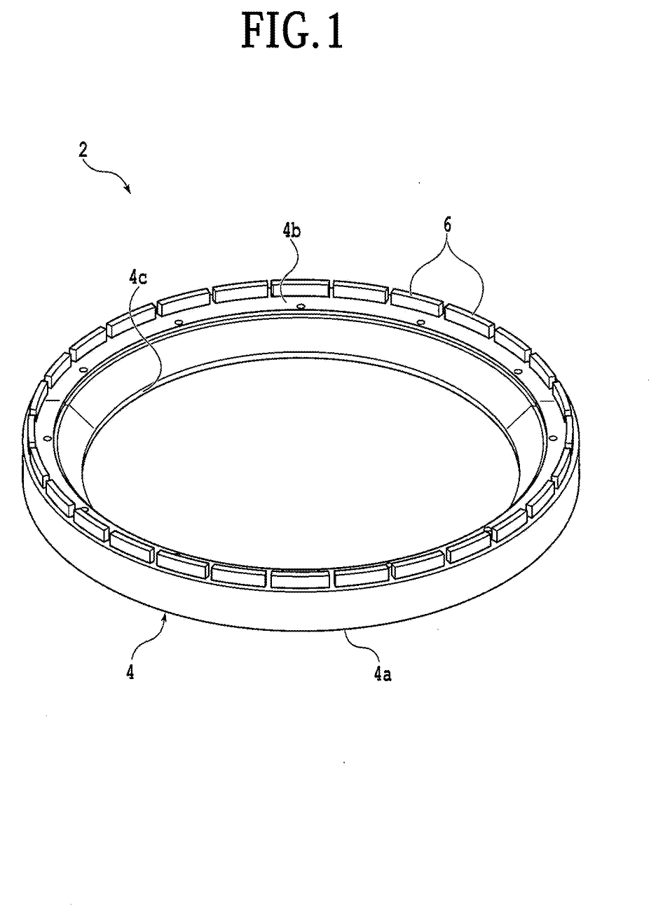

An embodiment of the present invention is hereinafter described in detail with reference to the attached drawings. FIG. 1 is a perspective view schematically illustrating a form of a semiconductor processing tool (grinding wheel) 2 to which a semiconductor processing grindstone 6 according to the present embodiment is mounted.

As illustrated in FIG. 1, the grinding wheel 2, which is a semiconductor processing tool, includes a wheel base 4 formed of metal such as stainless steel or aluminum as the material and the semiconductor processing grindstone 6.

The wheel base 4 is formed in a circular ring shape and has a first side 4a and a second side 4b that form both ends in an axial direction of the wheel base 4 and that are formed in parallel with each other. At the center of the wheel base 4, a circular opening 4c is formed to penetrate the wheel base 4 from the first side 4a to the second side 4b along the axis of the wheel base 4. The second side 4b is provided with a groove (not illustrated) along a circumferential direction, and a plurality of grinding stones (semiconductor processing grindstones) 6 are annularly arranged in the groove.

The semiconductor processing grindstones 6 are now described in detail. The semiconductor processing grindstones 6 according to the present embodiment each include numerous abrasive grains and a binder that binds the abrasive grains together.

Abrasive grains are, for example, formed of diamond, cubic boron nitride (CBN), or the like. Note that the material, average grain size, shape, and the like of the abrasive grains can be selected as appropriate according to the specification and the like of the semiconductor processing grindstones 6.

The semiconductor processing grindstones 6 are obtained by, for example, mixing the materials indicated in the following example of composition and hardening the materials of the binder (materials other than abrasive grains; water, magnesium chloride, and magnesium oxide). Note that the numerical values represent the ratio of volume of the materials.

(Example of composition) Abrasive grains: magnesium chloride (MgCl₂): water: magnesium oxide (MgO) = 24: 32: 31: 13

More specific steps are, for example, as follows: First, magnesium oxide and abrasive grains are mixed in a solution of magnesium chloride, and then, the resultant mixture is poured into a mold. Reaction occurs between water, magnesium chloride, and magnesium oxide, which are materials of the binder, and the mixture naturally hardens in approximately four hours to ten days. After the mixture has hardened, the hardened mixture is taken out from the mold, and a semiconductor processing grindstone 6 in a form in which abrasive grains are bound by the binder is obtained.

The mold has, for example, a cavity of a size of several millimeters to several centimeters, and the semiconductor processing grindstone 6 is formed in the same shape as this internal space. As one example, the cavity and the semiconductor processing grindstone 6 are formed in a rectangular parallelepiped with dimensions of approximately, 4 mm × 20 mm × 5 mm.

The semiconductor processing grindstones 6 formed in the manner described above are attached to the wheel base 4, and the grinding wheel 2 illustrated in FIG. 1 is manufactured. The number of pieces of semiconductor processing grindstones 6 to be attached to one wheel base 4 is decided according to the size and the like of the wheel base 4. For example, 28 pieces of semiconductor processing grindstones 6 having the dimensions described above are attached to the wheel base 4 having a diameter of approximately 200 mm, while 42 pieces of such semiconductor processing grindstones 6 are attached to the wheel base 4 having a diameter of approximately 300 mm.

Note that the abovementioned composition of the materials of the semiconductor processing grindstones 6 is merely an example, and the type of the materials used for the binder, the contained amount of each material, the ratio of abrasive grains to the binder, and the like are not limited to the composition described above. For example, when the same materials as those described above are used, each material can be contained as appropriate in an amount within the following ranges: with the total volume of the materials of the semiconductor processing grindstone 6 including all of the abrasive grains and the materials of the binder being 100, abrasive grains may be contained in an amount within the range of 5 to 50 by volume, magnesium chloride may be contained in an amount within the range of 10 to 50 by volume, water may be contained in an amount within the range of 10 to 50 by volume, and magnesium oxide may be contained in an amount within the range of 5 to 50 by volume. More preferably, abrasive grains are contained in an amount within the range of 15 to 35 by volume, magnesium chloride is contained in an amount within the range of 20 to 40 by volume, water is contained in an amount within the range of 20 to 40 by volume, and magnesium oxide is contained in an amount within the range of 5 to 30 by volume.

The binder of the semiconductor processing grindstone 6 manufactured from and by the abovementioned materials and method is a material called magnesia cement. Magnesia cement is a material obtained by mixing magnesium oxide, water, and magnesium salt and hardening the resultant mixture. The binder obtained after hardening includes magnesium oxide and magnesium salt.

As magnesium salt, for example, other than magnesium chloride, an appropriate amount of magnesium sulfate (MgSO₄) or other types of magnesium salt can be used. One type of magnesium salt may be contained in the binder, or a plurality of types of magnesium salt may be used as part of the material of the binder.

In a case where magnesium salt other than magnesium chloride is to be used as the material of the binder, the amount of magnesium salt is only required to be adjusted such that, when the magnesium salt to be used is replaced with magnesium chloride of the same mole number, the ratio of magnesium chloride to the total volume of the materials of the grindstone falls within the range described above.

Moreover, as the material of magnesia cement, magnesium hydroxide (MgOH) may be used in place of magnesium oxide. The materials of the binder may hence include magnesium hydroxide instead of magnesium oxide or include both magnesium oxide and magnesium hydroxide.

In a case where magnesium hydroxide is used in place of or in addition to magnesium oxide as the material of the binder, the amount of magnesium hydroxide is only required to be adjusted such that, when the magnesium hydroxide to be used is replaced with magnesium oxide of the same mole number, the ratio of magnesium oxide to the total volume of the materials of the grindstone falls within the range described above.

Besides, appropriate substances that have not been mentioned above may be included in the semiconductor processing grindstone 6 as the material of the binder or for other purposes.

The hardening reaction of the materials of the binder starts and proceeds when the abovementioned substances are mixed; no step of sintering, for example, is necessary for hardening. Hence, unlike vitrified bonds, for example, the binder includes no vitreous material unless a vitreous material (for example, silicon dioxide) is separately mixed therein.

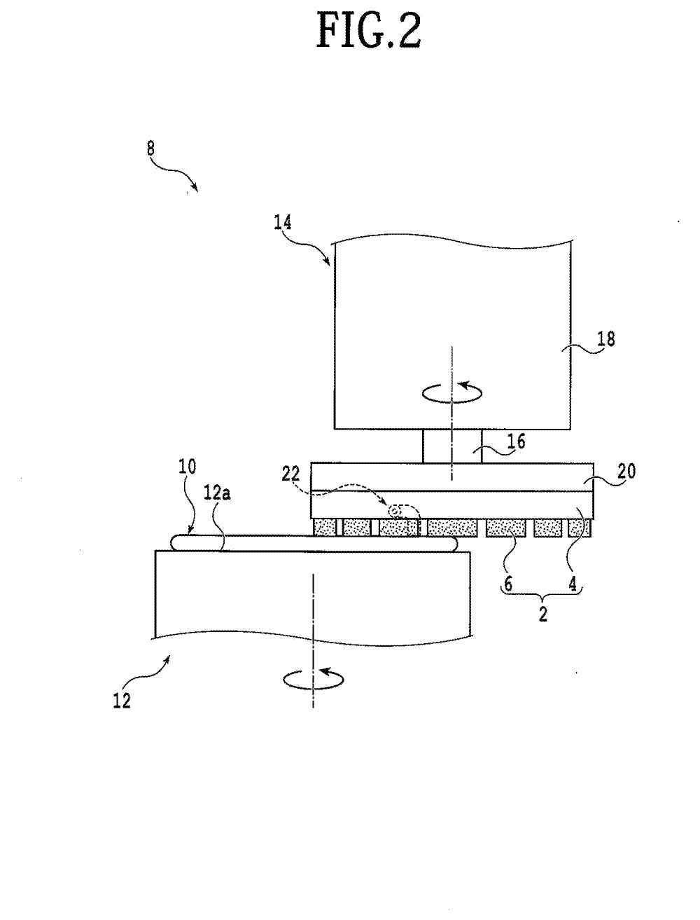

The grinding wheel 2 including the semiconductor processing grindstones 6 and the wheel base 4 described above is, for example, used by being attached to a grinding unit of a grinding apparatus. FIG. 2 is a side elevational view schematically illustrating a manner of grinding processing performed on a workpiece 10 by a grinding apparatus 8.

The workpiece 10 is an object including a semiconductor as a material and being subjected to processing, and is, for example, a wafer including silicon as the material. Note that the workpiece 10 may partially include a semiconductor as the material or in whole be formed with a semiconductor as the material.

The grinding apparatus 8, which is a processing apparatus, includes a chuck table 12 that holds the workpiece 10 and a grinding unit 14 that grinds the workpiece 10 held on the chuck table 12.

The chuck table 12 is connected to an unillustrated suction source. When the negative pressure generated by the suction source is caused to act on the workpiece 10 placed on an upper surface 12a, the chuck table 12 holds the workpiece 10 under suction on the upper surface 12a. In this way, the upper surface 12a of the chuck table 12 functions as a holding surface that holds the workpiece 10. Further, the chuck table 12 is configured to be rotatable about a rotational axis transverse to the upper surface 12a by operation of an unillustrated rotary drive source.

The grinding unit 14 includes a substantially cylindrical spindle 16, a housing 18 that accommodates the spindle 16, and a wheel mount 20 connected to a lower end of the spindle 16.

In the grinding apparatus 8, the chuck table 12 is mounted in a posture lying substantially along a horizontal direction, while the spindle 16 is attached to the grinding unit 14 such that an axial direction extends along a direction substantially vertical to the upper surface 12a of the chuck table 12. The orientation of the axis of the spindle 16 is substantially along the vertical direction. The spindle 16 has one end (upper end side) to which an unillustrated rotary drive source such as a motor is connected, and rotates about an axis extending substantially along the vertical direction by operation of the rotary drive source.

The grinding wheel 2 is fixed to the wheel mount 20 in a state in which a lower surface of the wheel mount 20 is in contact with the first side 4a of the wheel base 4. The second side 4b of the wheel base 4 to which the semiconductor processing grindstones 6 are mounted is oriented downward and faces the upper surface (holding surface) 12a of the chuck table 12.

Above the upper surface (holding surface) 12a of the chuck table 12, a processing liquid supply unit 22, which is a nozzle, is provided. At the time of grinding processing, such liquid as pure water that is used as the processing liquid is supplied to the upper surface of the workpiece 10 and the grinding wheel 2 from the processing liquid supply unit 22. Note that the processing liquid may be supplied from the processing liquid supply unit 22 toward the upper surface of the workpiece 10 or the grinding wheel 2 or both of them. Further, instead of the nozzle illustrated in FIG. 2, for example, a processing liquid supply unit as a mechanism that supplies processing liquid to the upper surface of the workpiece 10 or the grinding wheel 2 through an unillustrated flow channel provided inside the grinding unit 14 may be provided in the grinding apparatus 8.

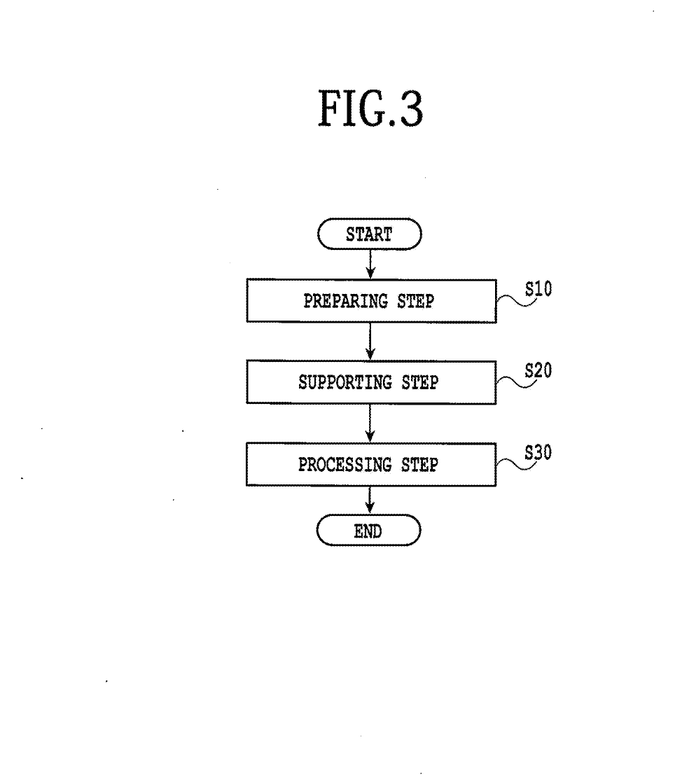

Next, the steps related to grinding processing of the workpiece 10 by the abovementioned semiconductor processing grindstones 6 and grinding apparatus 8 are described. FIG. 3 is a flowchart illustrating an example of steps related to a processing method of the workpiece 10 and a manufacturing method of semiconductor parts.

First, the semiconductor processing grindstones 6 are manufactured from and by the materials and the steps described above and attached to the wheel base 4, so that the grinding wheel 2, which is a semiconductor processing tool, is obtained (see FIG. 1). The grinding wheel 2 is attached to the wheel mount 20 of the spindle 16 included in the grinding unit 14 of the grinding apparatus 8 (see FIG. 2). In this way, the semiconductor processing grindstones 6 are prepared (preparing step S10).

Next, the workpiece 10 is supported on the chuck table 12 (supporting step S20). The workpiece 10 is placed on the holding surface 12a, supplied with a negative pressure from an unillustrated suction source, and thereby held under suction on the holding surface 12a.

Following this, grinding processing using the semiconductor processing grindstones 6 is performed on the workpiece 10 supported on the chuck table 12 (processing step S30; see FIG. 2). In a state in which the chuck table 12 and the grinding unit 14 are positioned relative to each other such that the semiconductor processing grindstones 6 are positioned above the workpiece 10, the chuck table 12 rotates about a rotational axis that extends substantially along the vertical direction. Meanwhile, the spindle 16 rotates together with the grinding wheel 2 about the rotational axis that extends substantially along the vertical direction, by operation of the rotary drive source (not illustrated). The semiconductor processing grindstones 6 attached to the grinding wheel 2 rotate while drawing an annular path.

From this state, the grinding unit 14 is lowered. When the semiconductor processing grindstones 6 come into contact with the workpiece 10, the upper surface side of the workpiece 10 is ground. As a result of this grinding, the height of the upper surface of the workpiece 10 gradually lowers, and the grinding unit 14 is further lowered (grinding fed) along with such lowering.

At this time, the workpiece 10 is ground by the abrasive grains, and the abrasive grains included in the semiconductor processing grindstones 6 are gradually worn. At the same time, the binder is also gradually worn, so that the abrasive grains embedded in the binder appear one by one. This action is called self-sharpening and maintains the grinding capability of the semiconductor processing grindstones 6 at a certain level.

At the time of grinding, processing swarf and heat are generated from the workpiece 10 and the semiconductor processing grindstones 6 that make a slide movement while being in contact with each other. Hence, such liquid as pure water that is used as processing liquid is supplied to the upper surface of the workpiece 10 and the grinding wheel 2 from the processing liquid supply unit 22, which is a nozzle, while grinding processing is being performed, and the processing swarf and heat are removed by the processing liquid.

When the workpiece 10 is ground to a desired thickness, grinding of the workpiece 10 is ended. After grinding is performed, the workpiece 10, which is a wafer, for example, is further subjected to such processing as dividing or other kinds of processes, so that semiconductor parts such as chips are manufactured.

In the processing step S30, water (pure water) as processing liquid, for example, is supplied to at least one of the workpiece 10 or the semiconductor processing grindstones 6, as described above. The supplied water is mixed with the processing swarf that has been generated in association with the grinding processing. The binder of each of the semiconductor processing grindstones 6 is magnesia cement. When the processing swarf generated by wearing of the binder comes into contact with water, the water is alkalified to have a pH value of equal to or more than 8 but equal to or less than 14 (as one example of a result of a verification test performed by the inventors of the present application, pH of approximately 12, for example). This is considered to be caused by the magnesium oxide included in the binder being dissolved in water and generating magnesium hydroxide (Mg(OH)₂).

That is, as a result of water being supplied as processing liquid at the time when the workpiece 10 is processed by the semiconductor processing grindstones 6 including magnesia cement as the binder, processing is performed with alkaline processing liquid. This can produce several advantageous effects in processing the workpiece 10.

For example, in a case where the processing swarf generated in association with processing includes a substance that dissolves in an alkaline solution, as a result of particles including such a substance being dissolved in an aqueous solution, the particles are collected in the aqueous solution. This reduces solid particles that adhere to the workpiece 10, surrounding apparatuses, and the like and can reduce contamination of the workpiece 10, surrounding apparatuses, and the like.

Moreover, in a case where a substance that dissolves in an alkaline solution is included in the workpiece 10, an effect of corrosion (etching) of the surface of the workpiece 10 can also be expected. For example, at the time of processing, minute cracks and irregularities are sometimes generated on the surface of the workpiece 10 due to force being applied from the semiconductor processing grindstones 6 thereto. As a result of the surface of the workpiece 10 being corroded by alkaline processing liquid, such cracks and irregularities are removed, producing such an effect that the strength of the workpiece 10 and the smoothness of the surface thereof are improved.

At the time of processing, a portion of the material of the workpiece 10 that forms the surface may be chipped to become particles, possibly becoming foreign matter for the workpiece 10. At that time, if the processing liquid has an alkaline property, its corrosion action makes it easier for the particles to dissolve in the processing liquid or to remove such particles from the surface of the workpiece 10.

Moreover, at the time of manufacturing the semiconductor processing grindstones 6, no step of sintering at high temperature or the like is needed as described above, and the mixture of the materials is only required to be poured into a mold and left, so that the materials of the binder naturally harden. Hence, huge energy consumption for heating or the like is unnecessary, and grindstones can be manufactured at low cost and less energy.

Examples of the workpiece 10 that are to be processed by the semiconductor processing grindstones 6 and that include a semiconductor as the material include various objects such as a substrate, a wafer, and an ingot. However, in obtaining the abovementioned effect available by alkaline processing liquid, preferably, the semiconductor included in the workpiece 10 is particularly of a type that has the property of being corroded by alkaline. Specific examples of such a semiconductor include silicon (Si), silicon carbide (SiC), germanium (Ge), gallium arsenide (GaAs), gallium nitride (GaN), and the like.

In particular, in a case where the workpiece includes silicon carbide as the semiconductor, vitrified bonded grindstones have mainly been used in the past for processing the workpiece due to the hardness of silicon carbide; however, as described above, vitrified bonded grindstones have the disadvantage of low self-sharpening capability. Using the semiconductor processing grindstones 6 including magnesia cement as the binder allows efficient processing while maintaining the processing quality by high self-sharpening capability.

The grindstone manufactured by mixing abrasives grains and a solution of magnesium oxide or magnesium hydroxide and magnesium salt is in itself a known technique called a magnesia cement grindstone and the like. However, in the field of semiconductor processing, magnesia cement grindstones have not been used. This is because magnesia cement that is not sintered at the time of manufacture has low holding strength of abrasive grains and a short grindstone lifespan, compared to vitrified bonds and metal bonds.

Yet, in recent years, with cheap and fine abrasive grains coming into widespread use, a short grindstone lifespan no longer causes a significant increase in running costs. Moreover, magnesia cement grindstones have the advantages of alkalifying processing liquid and reducing energy consumption, as described above. If such advantages outweigh the disadvantages, semiconductor processing grindstones 6 that include magnesia cement as the binder can sufficiently be of practical use as a grindstone of a new type that can be used for processing objects including a semiconductor as the material.

Note that, in the above description, a case where the workpiece 10 is subjected to grinding processing has been described, but examples of processing using the semiconductor processing grindstone also include polishing processing, cutting processing, and the like, in addition to grinding processing.

The polishing apparatus, which is a processing apparatus used for polishing processing, is an apparatus similar to the grinding apparatus 8 illustrated in FIG. 2, for example, and includes a chuck table that holds a workpiece and a polishing unit as a processing unit that performs polishing processing on the workpiece held on the chuck table.

The polishing unit includes a spindle to which a polishing pad as the semiconductor processing tool is mounted and that rotates together with the polishing pad, and polishes the workpiece by bringing the polishing pad into contact with the workpiece while making the polishing pad rotate. When polishing processing (processing step) is carried out, water as processing liquid is supplied from the processing liquid supply unit, which is a nozzle or the like, to at least one of the workpiece or the polishing pad. The polishing pad is, similarly to the semiconductor processing grindstones 6, formed in a disk-shape, for example, by semiconductor processing grindstones including magnesia cement as the binder.

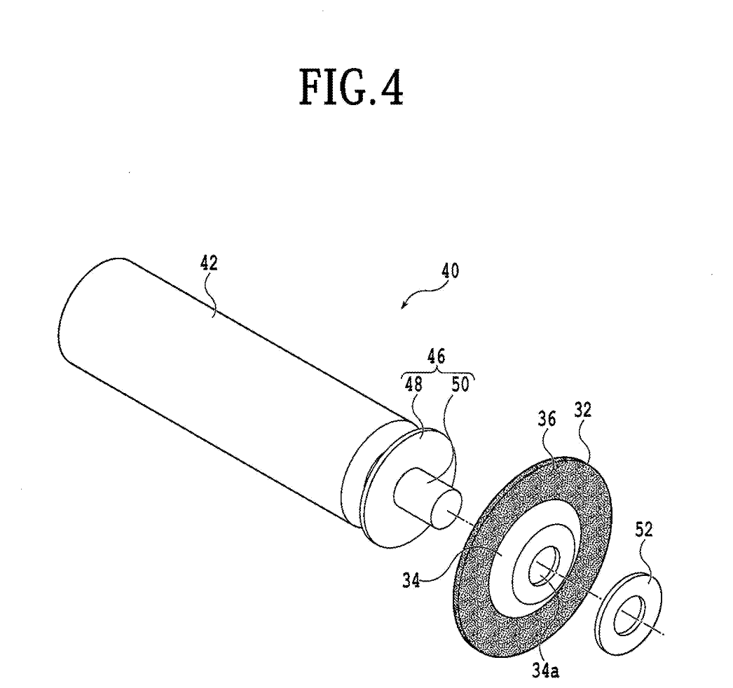

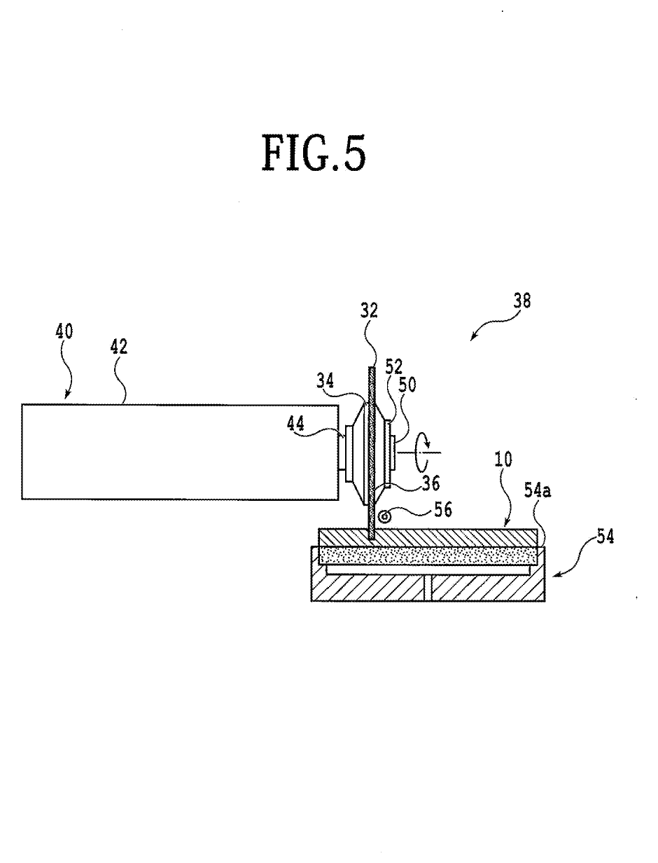

Now, forms of a cutting apparatus, which is a processing apparatus used for cutting processing, and a cutting blade, which is a semiconductor processing tool attached to the cutting apparatus, are described. FIG. 4 is an exploded perspective view of a cutting unit 40 schematically illustrating forms of a cutting blade 32 and the cutting unit 40 attached thereto. FIG. 5 is a side elevational view schematically illustrating a manner of the cutting processing performed on the workpiece 10 by a cutting apparatus (processing apparatus) 38.

The cutting blade 32 is, for example, of a hub type (hub blade) and includes an annular hub base 34 made of metal or the like and a cutting edge 36 that is attached thereto along an outer peripheral edge of the hub base 34. The cutting edge 36 is a semiconductor processing grindstone formed by abrasive grains made of diamond or the like and a binder including magnesia cement, but unlike the semiconductor processing grindstones 6 illustrated in FIGS. 1 and 2, is formed in an annular shape. The hub base 34, which forms a central portion of the cutting blade 32, is provided with a circular opening 34a that penetrates a region including the center of the hub base 34 in the axial direction.

Note that, as the cutting blade, for example, a cutting blade of a washer type (washer blade) can also be used. A washer blade includes no hub base and only an annular cutting edge.

The cutting apparatus 38, which is the processing apparatus that performs cutting processing on the workpiece 10, includes the cutting unit 40, which is a processing unit, and a chuck table 54. The cutting unit 40 includes a cylindrical housing 42, which accommodates a cylindrical spindle 44 that is disposed along the horizontal direction. While one end side (distal end side) of the spindle 44 is exposed from the housing 42, the other end side (proximal end side) of the spindle 44 is coupled to a rotary drive source such as a motor (not illustrated). When the rotary drive source is operated, the cylindrical spindle 44 rotates about an axis of the spindle 44.

To the distal end portion of the spindle 44, a blade mount 46 is mounted. The blade mount 46 is, for example, fixed to the distal end portion of the spindle 44 by a fastening bolt or the like and rotates in unison with the spindle 44.

The blade mount 46 includes a disk-shaped flange portion 48 and a cylindrical support shaft 50 that protrudes from a central portion on the face side of the flange portion 48. The cutting blade 32 is attached to the blade mount 46. In a state in which the cutting blade 32 is attached to the blade mount 46, an outer peripheral portion of the flange portion 48 is in contact with the reverse side of the cutting blade 32, and the support shaft 50 enters the opening 34a of the hub base 34.

In an outer peripheral surface of the distal end portion of the support shaft 50, an unillustrated thread groove is formed. To this thread groove, an annular nut 52 is fastened. This fixes the cutting blade 32 to the blade mount 46.

As illustrated in FIG. 5, below the cutting unit 40 in the cutting apparatus 38, the chuck table 54 is provided. The chuck table 54 is connected to an unillustrated suction source, and holds the workpiece 10 under suction on an upper surface (holding surface) 54a by causing the negative pressure generated by the suction source to act on the workpiece 10 placed on the upper surface 54a. Further, the chuck table 54 is configured to be rotatable about a rotational axis transverse to the upper surface 54a by operation of an unillustrated rotary drive source.

Above the upper surface (holding surface) 54a of the chuck table 54, a processing liquid supply unit 56, which is a nozzle for jetting water as processing liquid, is provided.

When cutting processing (processing step) is carried out, the workpiece 10 is held on the holding surface 54a of the chuck table 54, and the spindle 44 attached to the cutting unit 40 rotates together with the cutting blade 32 by operation of the rotary drive source (not illustrated). By an unillustrated moving mechanism, the spindle 44 and the chuck table 54 are moved relative to each other. By the cutting edge 36 of the cutting blade 32 cutting into the workpiece 10 held on the chuck table 54, the workpiece 10 illustrated in FIG. 5 is cut. The processing liquid supply unit 56 jets and supplies liquid such as pure water that is used as the processing liquid to the cutting blade 32 and the workpiece 10.

The depth to which the cutting blade 32 cuts into the workpiece 10 can be adjusted by the distance between the spindle 44 and the chuck table 54 at the time of cutting. When the cutting edge 36 partially cuts in to the workpiece 10 in a thickness direction, a cutting groove is formed in the face side of the workpiece 10.

When the cutting edge 36 wholly cuts in to the workpiece 10 in the thickness direction thereof, the workpiece 10 is cut and divided (fully cut) at the position. In this case, cutting of the workpiece 10 and dividing of the workpiece 10 are carried out at the same time in the processing step S30 (see FIG. 3). Note that, when full-cut is to be carried out, a protective member (support member) such as a resin tape is preferably affixed to the workpiece 10 so as to prevent the cutting blade 32 from cutting into the chuck table 54 and to make it easier to handle the workpiece 10 that has been divided.

When cutting processing is to be caried out, processing swarf originating from the binder including magnesia cement is generated due to cutting by the cutting edge 36 of the cutting blade 32 and is mixed with water supplied as processing liquid, alkalifying the processing liquid. This alkaline processing liquid offers a cleaning effect by the dissolution of the processing swarf as described above. In a case where the workpiece 10 includes a semiconductor having a property of dissolving by alkali, an effect of corrosion (etching) can also be obtained.

As described above, semiconductor processing grindstones including magnesia cement as the binder can be used for various kinds of processing in addition to grinding.

Other structural and methodological details according to the abovementioned embodiment are not limited to those described in the embodiment and can appropriately be modified within a range not deviating from the scope of object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A semiconductor processing grindstone used for processing a workpiece including a semiconductor as a material, the semiconductor processing grindstone comprising:
abrasive grains; and
a binder that binds the abrasive grains together, wherein
the binder includes magnesium oxide and magnesium salt.

2. The semiconductor processing grindstone according to claim 1, wherein the semiconductor processing grindstone is used for at least one of cutting processing that cuts the workpiece, grinding processing that grinds the workpiece, or polishing processing that polishes the workpiece.

3. A semiconductor processing tool used for processing a workpiece including a semiconductor as a material, the semiconductor processing tool comprising:
a semiconductor processing grindstone including abrasive grains and a binder that binds the abrasive grains together, the binder including magnesium oxide and magnesium salt.

4. The semiconductor processing tool according to claim 3, wherein the semiconductor processing tool is used for at least one of cutting processing that cuts the workpiece, grinding processing that grinds the workpiece, or polishing processing that polishes the workpiece.

5. A processing method that uses a semiconductor processing grindstone and processes a workpiece including a semiconductor as a material, the processing method comprising:
preparing the semiconductor processing grindstone including abrasive grains and a binder that binds the abrasive grains together, the binder including magnesium oxide and magnesium salt;
supporting the workpiece; and
processing the supported workpiece by using the semiconductor processing grindstone.

6. The processing method according to claim 5, wherein, in the processing the workpiece, at least one of cutting processing that cuts the workpiece, grinding processing that grinds the workpiece, or polishing processing that polishes the workpiece is carried out.

7. The processing method according to claim 5, wherein, in the processing the workpiece, water is supplied to at least one of the workpiece or the semiconductor processing grindstone.

8. The processing method according to claim 7, wherein, in the processing the workpiece, liquid property of the supplied water is changed such that the water has a pH value of equal to or more than 8 but equal to or less than 14 by causing the water to come into contact with the binder.

9. A manufacturing method of semiconductor parts for manufacturing semiconductor parts by using a semiconductor processing grindstone and processing a workpiece including a semiconductor as a material, the manufacturing method comprising:
preparing the semiconductor processing grindstone including abrasive grains and a binder that binds the abrasive grains together, the binder including magnesium oxide and magnesium salt;
supporting the workpiece; and
processing the supported workpiece by using the semiconductor processing grindstone.

10. The manufacturing method of semiconductor parts according to claim 9, wherein, in the processing the workpiece, at least one of cutting processing that cuts the workpiece, grinding processing that grinds the workpiece, or polishing processing that polishes the workpiece is carried out.

11. The manufacturing method of semiconductor parts according to claim 9, wherein, in the processing the workpiece, water is supplied to at least one of the workpiece or the semiconductor processing grindstone.

12. The manufacturing method of semiconductor parts according to claim 11, wherein, in the processing the workpiece, liquid property of the supplied water is changed such that the water has a pH value of equal to or more than 8 but equal to or less than 14 by causing the water to come into contact with the binder.
